(19) United States
(12) Patent Application Publication
(10) Pub. No.: US 2026/0172049 A1
(43) Pub. Date: Jun. 18, 2026

(54) FASTER DECOMPRESSION BY CONSTRAINING DATA COMPRESSION

(71) Applicant: Advanced Micro Devices, Inc., Santa Clara, CA (US)

(72) Inventors: Ashish Sriram, Bengaluru (IN); Samantray Biplab Raut, Bangalore (IN)

(73) Assignee: Advanced Micro Devices, Inc., Santa Clara, CA (US)

(21) Appl. No.: 18/984,609

(22) Filed: Dec. 17, 2024

(51) Int. Cl. H03M 7/30

(52) U.S. Cl. CPC H03M 7/6082; H03M 7/6005; H03M 7/6011

(57) ABSTRACT

Data compression for fast decompression includes generating, by computer hardware, a compressed data stream by compressing data using a data compression technique. The compressed data stream is generated by the computer hardware while enforcing one or more compression constraints for the compression technique. A metadata frame is generated by the computer hardware specifying the one or more compression constraints. The compressed data stream including the metadata frame is output by the computer hardware. A tuner may be used to specify a particular decompression level implemented during compression and/or to select a particular compression having a particular configuration for performing compression.

### TECHNICAL FIELD

This disclosure relates to data compression and decompression and, more particularly, to lossless data compression and decompression.

### BACKGROUND

Data warehousing, streaming, and broadcasting are examples of different applications that involve cloud-computing workloads that operate on large quantities of data. These applications store data on servers and transfer that data to multiple clients on demand. With these types of applications, data retrieval is often a performance bottleneck. One way in which performance has been improved is to compress the data, store the compressed data, and transfer the compressed data on demand to client devices. This computing model is referred to as “compress once, decompress multiple times.” In this computing model, the majority of the compute workloads perform decompression of the compressed data.

Data compression refers to a technological process performed by hardware or a combination of hardware and software in which source data specified as a particular number of bits is encoded (e.g., compressed) into compressed data formed of fewer bits than the source data. The size of the data, as compressed, is reduced compared to the size of the original, uncompressed data. Lossless compression is a type of compression that uses an invertible encoding process meaning that the original, uncompressed data may be recovered from the compressed data without any loss of information.

There are a variety of different types of lossless data compression techniques available. Example compression techniques include, but are not limited to, LZ4, LZ4HC, Snappy, ZLIB, LZMA, ZSTD, and BZIP2. In general, each compression technique utilizes a different Application Programming Interface (API) set and uses a different specification for representing compressed data. That is, there is no “one size fits all” specification for representing compressed data that has been standardized across different compression techniques.

Other compression formats have been introduced that seek to optimize decompression speed. Adoption of these compression formats, however, has been limited due to a number of reasons including, for example, incompatibility with other popular compression formats such as LZ4, ZLIB, and ZSTD, the difficulty in integrating new compression formats into existing systems and/or computing frameworks, and/or licensing fees.

### SUMMARY

In one or more examples, a method includes generating, by electronic hardware, a compressed data stream by compressing data using a data compression technique. The compressed data stream is generated while enforcing one or more compression constraints for the compression technique. The method includes generating, by the electronic hardware, a metadata frame specifying the one or more compression constraints. The method includes outputting, by the electronic hardware, the compressed data stream including the metadata frame.

The foregoing and other implementations can each optionally include one or more of the following features, alone or in combination. Some example implementations include all the following features in combination.

In some aspects, enforcing the one or more compression constraints includes using at least one of a minimum offset for a match candidate within a search buffer or a maximum offset for the match candidate within the search buffer.

In some aspects, enforcing the one or more compression constraints includes using at least one of a minimum match length or a maximum match length.

In some aspects, enforcing the one or more compression constraints includes parsing at least a minimum number of literals in the data prior to accepting a match.

In some aspects, enforcing the one or more compression constraints includes restricting a number of repeated offsets.

In some aspects, enforcing the one or more compression constraints includes restricting use of an external dictionary for specifying match candidates.

In some aspects, enforcing the one or more compression constraints includes limiting a number of bits generated by an encoder.

In some aspects, enforcing the one or more compression constraints includes using a same entropy table for an encoder for a predetermined number of blocks.

In some aspects, the method includes detecting the metadata frame for the compressed data stream, detecting the one or more compression constraints enforced while generating the compressed data stream from the metadata frame, and providing the compressed data stream to a selected decompressor of a plurality of decompressors. The selected decompressor is selected based on the one or more compression constraints detected.

In some aspects, the one or more compression constraints are specified as a decompression level. Generating the compressed data stream includes selecting a selected compressor from a plurality of compressors based on the decompression level and compressing the data using the selected compressor.

In one or more examples, a method includes, in response to receiving a compressed data stream, checking, by computer hardware, the compressed data stream for a metadata frame. The method includes, in response to detecting the metadata frame, detecting, by the computer hardware and from the metadata frame, one or more compression constraints enforced during generation of the compressed data stream. The method includes selecting a selected decompressor from a plurality of different decompressors based on the one or more compression constraints. The method includes decompressing, by the computer hardware, the compressed data stream using the selected decompressor.

The foregoing and other implementations can each optionally include one or more of the following features, alone or in combination. Some example implementations include all the following features in combination.

In some aspects, each decompressor of the plurality of different decompressors is optimized for decompressing compressed data streams for a particular set of the one or more compression constraints.

In one or more examples, a system includes a hardware device capable of implementing operations. The operations include generating a compressed data stream by compressing data using a data compression technique. The compressed data stream is generated while enforcing one or more compression constraints for the compression technique. The operations include generating a metadata frame specifying the one or more compression constraints. The operations include outputting the compressed data stream including the metadata frame.

In one or more examples, the hardware device may be implemented as a hardware processor that is capable of executing program code. In one or more examples, the hardware device may be circuitry that is capable of performing the operations described herein.

The foregoing and other implementations can each optionally include one or more of the following features, alone or in combination. Some example implementations include all the following features in combination.

In some aspects, enforcing the one or more compression constraints includes using at least one of a minimum offset for a match candidate within a search buffer or a maximum offset for the match candidate within the search buffer.

In some aspects, enforcing the one or more compression constraints includes using at least one of a minimum match length or a maximum match length.

In some aspects, enforcing the one or more compression constraints includes parsing at least a minimum number of literals in the data prior to accepting a match.

In some aspects, enforcing the one or more compression constraints includes restricting a number of repeated offsets.

In some aspects, enforcing the one or more compression constraints includes restricting use of an external dictionary for specifying match candidates.

In some aspects, enforcing the one or more compression constraints includes limiting a number of bits generated by an encoder.

In some aspects, enforcing the one or more compression constraints includes using a same entropy table for an encoder for a predetermined number of blocks.

In one or more examples, a computer program product includes a computer readable storage medium having program instructions embodied therewith. The program instructions are executable by computer hardware, e.g., a hardware processor, to cause the computer hardware to execute the various operations as described within this disclosure.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the disclosed technology to only the examples shown. Various aspects and advantages will become apparent upon review of the following detailed description and upon reference to the drawings.

FIG. 1 illustrates a computing environment including a compression framework and a decompression framework in accordance with one or more implementations of the disclosed technology.

FIG. 2A illustrates an example of uncompressed data.

FIG. 2B illustrates an example of data output from a dictionary coder.

FIG. 3 illustrates a method of compressing data in accordance with one or more implementations of the disclosed technology.

FIG. 4 illustrates a method of decompressing data in accordance with one or more implementations of the disclosed technology.

FIG. 5 illustrates a data structure for a metadata frame in accordance with one or more implementations of the disclosed technology.

FIG. 6 is a table illustrating different compression constraints that may be specified by a metadata frame in accordance with one or more implementations of the disclosed technology.

FIG. 7 illustrates example bit values specified for a metadata segment of a metadata frame.

FIG. 8 illustrates a decompression framework in accordance with one or more implementations of the disclosed technology.

FIG. 9 illustrates another implementation of a compression framework in accordance with one or more implementations of the disclosed technology.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to data compression and decompression and, more particularly, to lossless data compression and decompression. In accordance with the implementations described within this disclosure, methods, systems, and computer program products are provided that are capable of compressing data in a manner that facilitates faster decompression of the compressed data. With conventional approaches to data compression, the objective typically is to maximize the amount of compression achieved. While the compressed data requires less memory for storage than the uncompressed data, the operations required to decompress the data may be onerous, requiring computations that require greater runtime.

In accordance with the disclosed technology, particular compression constraint(s) may be specified and enforced during compression operations that result in reduced runtime for decompressing the compressed data. That is, computational complexity for decompressing the data, and hence the time required to decompress the data, may be controlled and reduced by enforcing particular compression constraints during compression of the data. Controlling the time required for performing decompression is particularly useful in cases where data may be compressed once (or fewer times) and decompressed many times. For example, compressed data may be stored on a server and distributed. The distribution may be to many different clients. The decompression may be performed by the requesting clients.

In one or more implementations, a compression framework is disclosed that is capable of receiving one or more specified compression constraints to be imposed by the compression framework while compressing data. The compression framework is capable of imposing the specified compression constraints to produce a compressed data stream that is format compliant.

In one or more implementations, the compression framework is capable of generating a metadata frame that specifies the particular compression constraints that were imposed or enforced while the data was compressed. The metadata frame may be included with the compressed data stream and output. As such, the metadata frame may be received with the compressed data stream by a receiving device for purposes of decompressing the compressed data stream.

In one or more implementations, a decompression framework is capable of interpreting the metadata frame that may be found in a received compressed data stream. By interpreting the metadata frame, the decompression framework is capable of selecting a particular decompressor that is suited or optimized for decompressing the compressed data given the particular compression constraints imposed during compression as specified by the metadata frame. The selected decompressor is capable of decompressing the compressed data in less time than a conventional decompressor would require.

In one or more implementations, because the compressed data stream is format compliant, a conventional decompressor is still able to decompress the compressed data stream. In many cases, the imposed compression constraints result in a conventional decompressor being capable of decompressing the compressed data stream in less time than had the compression constraints not been imposed. Still, a decompression framework as described within this disclosure is capable of providing improved performance over a conventional decompressor in that the compressed data stream may be decompressed in less time than would be required for a conventional decompressor to decompress the compressed data stream. In any case, data compressed as described herein by imposing one or more compression constraints still may be decompressed faster than otherwise would have been the case while still storing the compressed data stream using open-source formats such as, for example, BZIP2, LZ4, LZMA, Snappy, ZLIB, and ZSTD.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

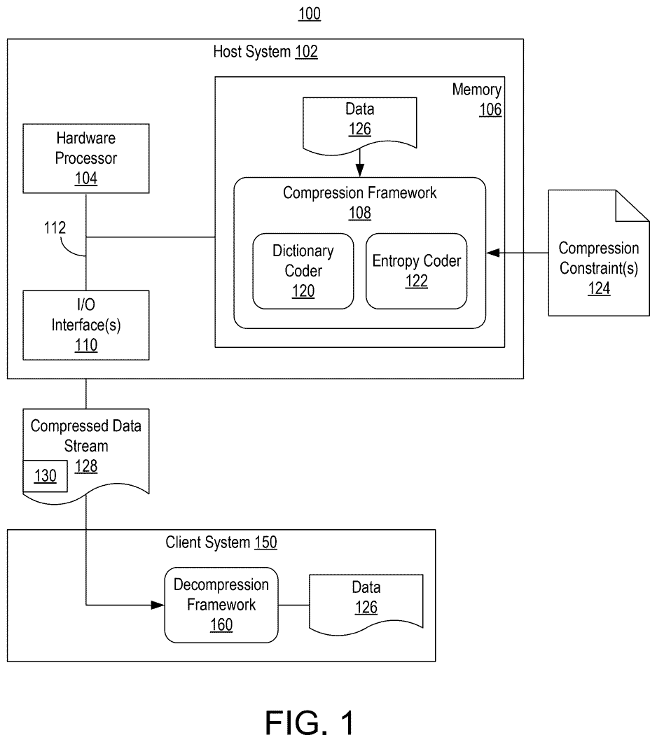

FIG. 1 illustrates a computing environment 100 that executes a compression framework and a decompression framework in accordance with one or more implementations of the disclosed technology. In the example, computing environment 100 includes a host system 102 and a client system 150. Host system 102 and client system 150 may communicate over a communication network (not shown).

The communication network may be implemented as or include any combination of the Internet, a mobile network, a Local Area Network (LAN), a Wide Area Network (WAN), a personal area network (PAN), one or more wired networks, one or more wireless networks, or the like. The communication network may include copper transmission cables, optical transmission fibers, wireless transmission, routers, firewalls, switches, gateway computers and/or edge devices including edge servers. As described in greater detail below, the various devices and/or systems illustrated in FIG. 1 may include respective network adapters or network interfaces in order to communicate over the communication network. In one or more examples, the communication network is implemented as a packet-switched network configured to convey packetized data.

Host system 102 and client system 150 each may be implemented as a data processing system. As used herein, the term “data processing system” refers to one or more hardware systems capable of processing data. Each hardware system may include one or more hardware processors and memory. Referring to FIG. 1, a hardware architecture for host system 102 is described in detail. It should be appreciated that a similar or same hardware architecture, though not illustrated in FIG. 1, may be used to implement client system 150.

Host system 102 includes a hardware processor 104. Hardware processor 104 may be implemented as one or more circuits capable of executing computer-readable program instructions (program instructions). The circuit(s) may comprise integrated circuits (ICs) or may be embedded within an IC. In one or more examples, hardware processor 104 may be embodied as a central processing unit (CPU). Hardware processor 104 may include one or more cores, for example, where each core is capable of executing program instructions. Hardware processor 104 may be implemented using any of a variety of architectures such as, for example, a complex instruction set computer architecture (CISC), a reduced instruction set computer architecture (RISC), a vector processing architecture, or other known architecture. For example, a hardware processor may be implemented using an x86 architecture (e.g., IA-32, IA-64), a Power Architecture, as an ARM processor, or the like.

Host system 102 can include memory 106. Memory 106 may be embodied as one or more computer-readable storage mediums. Memory 106 may include a volatile memory and a non-volatile memory (not shown). The volatile memory may be embodied as random-access memory (RAM) and may include cache memory. The volatile memory may be referred to as “runtime memory.” The non-volatile memory may include a non-volatile magnetic medium and/or a solid-state medium (typically called a “hard drive”). The non-volatile memory also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 106 is capable of storing program instructions and/or data such that hardware processor 104 is capable of executing the program instructions to perform one or more operations as described within this disclosure. For example, the program instructions can include an operating system, one or more application programs, other program code such as compression framework 108, and program data. Hardware processor 104, in executing the computer-readable program instructions, is capable of performing the various operations described herein that are attributable to a computer.

Host system 102 may include one or more Input/Output (I/O) interfaces 110. I/O interface(s) 110 allow host system 102 to communicate with one or more external devices and/or communicate over a communication network as described. Examples of I/O interfaces 110 may include, but are not limited to, network cards, modems, network adapters (wired and/or wireless), hardware controllers, etc. Examples of external devices also may include devices that allow a user to interact with host system 102 (e.g., a display, a keyboard, and/or a pointing device) and/or other devices such as accelerator card.

Bus 112 represents one or more of any of a variety of communication bus structures. By way of example, and not limitation, bus 112 may be implemented as a Peripheral Component Interconnect Express (PCIe) bus. Bus 112 couples to each of hardware processor 104, memory 106, and I/O interface(s) 110 through respective interface circuitry thereby allowing the devices to communicate. Bus 112 may represent a plurality of buses that may be interconnected and/or hierarchically organized.

Host system 102 is only one example implementation. Host system 102 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

Other examples of a hardware processor that is capable of performing the operations described herein (e.g., whether in reference to compression or decompression) may include a Graphics Processing Unit (GPU) and a programmable IC. A programmable IC may include an IC that includes at least some programmable circuitry. Programmable logic is an example of programmable circuitry. An example of a programmable IC may include a Field Programmable Gate Array (FPGA) or other type of adaptive system that may be updated in the field.

In one or more examples, compression framework 108 may be embodied as dedicated circuitry implemented in programmable circuitry and/or logic. In one or more other examples, the compression framework 108 may be embodied as hardened circuit blocks of an IC, e.g., in an Application Specific IC (ASIC). In still one or more other examples, host system 102 may include a hardware accelerator that implements/executes compression framework 108. The hardware accelerator may be implemented as a GPU, a programmable IC (e.g., an FPGA), an ASIC, or the like.

The term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

Client system 150, as noted, also may be implemented as a data processing system having a hardware processor capable of executing program code, memory, and an I/O interface coupled by a communication bus. Client system 150 is capable of executing program instructions to perform one or more operations as described within this disclosure. For example, the program instructions can include an operating system, one or more application programs, other program code such as decompression framework 160, and program data. In one or more other examples, client system 150 may include or use other types of processing devices as described in connection with host system 102 capable of executing decompression framework 160.

In one or more examples, decompression framework 160 may be embodied as dedicated circuitry implemented in programmable circuitry and/or logic. In one or more other examples, the decompression framework 160 may be embodied as hardened circuit blocks of an IC, e.g., in an ASIC. In still one or more other examples, client system 150 may include a hardware accelerator that implements/executes decompression framework 160. The hardware accelerator may be implemented as a GPU, a programmable IC (e.g., an FPGA), an ASIC, or the like.

Further, client system 150 may include a hardware accelerator to perform decompression operations of decompression framework 160.

Examples of client system 150 may include, but are not limited to, a workstation, a desktop computer, a computer terminal, a mobile computer, a laptop computer, a netbook computer, a tablet computer, a smart phone, a personal digital assistant, a smart watch, smart glasses, a gaming device, a set-top box, an information appliance, a smart television, a streaming device, and the like.

The example of FIG. 1 is not intended to suggest any limitation as to the scope of use or functionality of example implementations described herein. Host system 102 and/or client system 150 are examples of computer hardware each capable of performing the various operations described within this disclosure. In this regard, host system 102 and/or client system 150 may include fewer components than shown or additional components not illustrated in FIG. 1 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a hardware processor may include at least some memory.

In the example of FIG. 1, compression framework 108 and decompression framework 160 are capable of implementing lossless compression and decompression. That is, decompression framework 160 is capable of recovering the original data as it existed prior to compression by compression framework 108. The implementations are capable of achieving improved speed for decompression in client system(s) 150. The improved speed (e.g., reduced runtime to perform decompression) may be achieved by balancing other metrics. The improved decompression speed achieved by decompression framework 160, for example, may result in a reduced compression ratio and/or reduced compression speed achieved by compression framework 108.

In one or more examples, compression framework 108 implements multi-stage compression. Compression framework 108 may include a dictionary coder 120 implementing the first stage of the multi-stage compression and an entropy coder 122 implementing a second stage of the multi-stage compression. The particular examples described herein such as dictionary coder 120 and/or entropy coder 122 are provided for purposes of illustration and not limitation. It should be appreciated that compression framework 108 may be implemented using techniques other than those specifically mentioned within this disclosure. In the example, compression framework 108 is capable of receiving one or more compression constraints 124 that are to be enforced or implemented by compression framework 108 while compressing data 126, which may be uncompressed data.

As generally known, dictionary coder 120 may operate over data 126 using a sliding window. If a same data pattern in a lookahead buffer is found in a dictionary of dictionary coder 120, the data may be encoded as a “match length and distance pair.” Compressed data may be output from dictionary coder 120 in the form of sequences of literals (l) and match length and distance pairs (e.g., “match-distance pairs” or “(m, d) pairs”). A sequence of one or more literals and/or one or more match-distance pairs may be referred to as an “<l, m, d> sequence.” In one or more examples, dictionary coder 120 may be implemented as an LZ77 compressor. Compressed (e.g., encoded) data output from dictionary coder 120 may be stored in any of a variety of known formats. Example data formats may include LZ4 or Snappy.

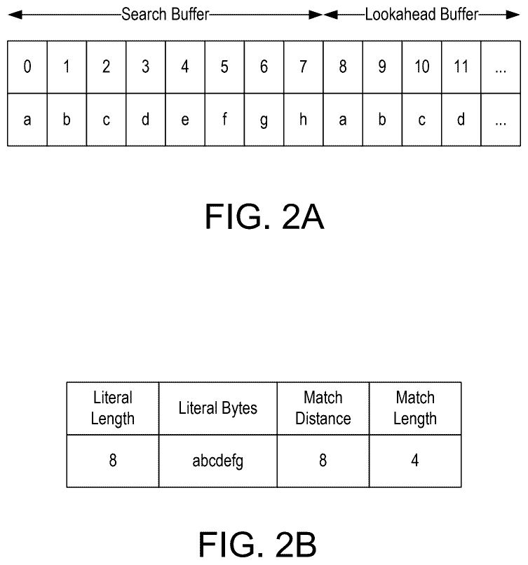

For purposes of illustration, consider an input data stream illustrated in FIG. 2A. The data stream of FIG. 2A illustrates uncompressed data (e.g., data 126). The input data stream of FIG. 2A has characters “abcdefghabcd” with positions 0 through 11. Dictionary coder 120 matches the pattern “abcd” at position 8 with the pattern “abcd” that starts at position 0. Dictionary coder 120 is capable of representing the data stream of FIG. 2A as an <l, m, d> sequence illustrated in FIG. 2B. FIG. 2B illustrates example data as output from dictionary coder 120 encoded in the LZ4 Block Format. The first portion of the data stream is specified as a plurality or sequence of literals of a particular length (e.g., 8 bytes). The matched portion may be represented using a match distance and a match length. The match distance specifies the number of characters earlier (e.g., to the left) that the matched bytes start (e.g., 8 bytes to the left of position 8 corresponding to position 0). The match length indicates the number of matching characters, which is 4 in this case corresponding to the characters “abcd.” During decompression as performed by decompression framework 160, literal bytes are copied as is while match bytes are copied from different offsets in previously decompressed data.

The <l, m, d> sequences output from dictionary coder 120 may be further compressed by entropy coder 122. Example implementations of encoding techniques that utilize both a dictionary coder and an entropy coder may include, but are not limited to, LZMA, ZLIB, or ZSTD.

In one or more examples, entropy coder 122 is implemented as a Dynamic Huffman Coder. Dynamic Huffman coding is an adaptive variant of Huffman coding. With Dynamic Huffman coding, symbols in an <l, m, d> sequence are mapped to prefix codes that are learned dynamically when new data is presented. These learned tables are also compressed and packed into the data stream. During decompression, the tables are decompressed first. Subsequently the tables are used to decompress the prefix codes into <l, m, d> sequences. Learning tables dynamically on entire input data adds overhead during compression and decompressing the tables adds computational overhead for decompression.

In one or more examples, entropy coder 122 is implemented as a Finite State Entropy (FSE) Coder. An FSE Coder is an entropy coder that combines the compression ratio of arithmetic coding, with a processing cost similar to Huffman coding. An FSE coder encodes symbols in <l, m, d> sequences using a prefix code followed by raw additional bits for granularity when the values are large. During decompression, when the number of additional bits to be read is large, additional branching and computational overhead is incurred to resolve the sequences.

In general, entropy coder 122 is capable of generating multiple encoded bits from the <l, m, d> sequences and placing those encoded bits in a “block.” Entropy coder 122 includes multiple blocks in a “frame.” Entropy coder 122 operates by building a probability model specifying how frequently characters occur in a data stream. In illustration, in the case where entropy coder 122 detects that “E” occurs more frequently than “Z,” entropy coder 122 chooses to represent “E” with fewer bits than would be used to represent “Z.” For example, entropy coder 122 may represent “E” using 1 bit (a 1-bit code) and represent “Z” using 5 bits (e.g., a 5-bit code). Operation of dictionary coder 120 reduces the size of the data being compressed. Operation of entropy coder 122 further reduces the size of the data output from dictionary coder 120.

In one or more examples, compression framework 108 and/or decompression framework 160 may be implemented as software frameworks that provide a set of unified APIs for supported compression and decompression techniques that may be integrated into applications. The software framework further may be optimized for use with a particular type or types (e.g., models and/or architectures) of hardware processors.

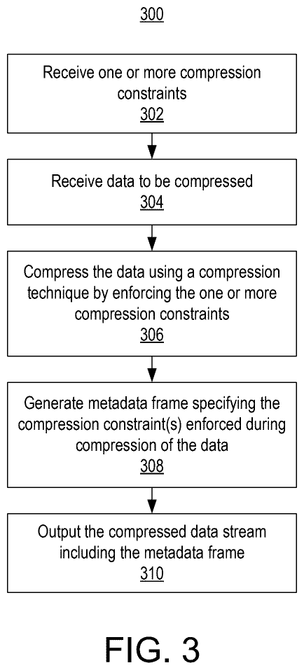

FIG. 3 illustrates a method 300 of compressing data in accordance with one or more implementations of the disclosed technology. Method 300 may be performed by host system 102 and, more particularly, by host system 102 through execution or implementation of compression framework 108.

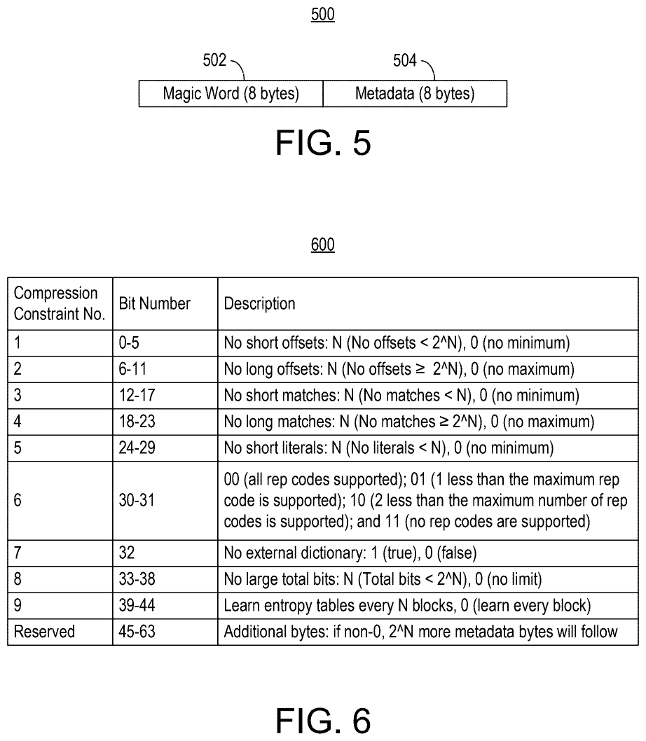

Referring to FIGS. 1 and 3, in block 302, compression framework 108 is capable of receiving one or more compression constraints 124. Compression constraints 124 may be specified as a user input, a preferences file, hard-coded in software, specified in a hardware register, or the like. In one or more examples, compression constraints 124 may be specified on an individual basis. That is, each particular compression constraint and corresponding parameter(s) for each compression constraint to be enforced while compressing data may be specified on an individual basis. Compression constraints 124 are described hereinbelow in greater detail in connection with FIGS. 5, 6, and 7.

In one or more other examples, one or more compression constraints 124 and corresponding parameter(s) may be specified as a decompression level. The decompression level, for example, may be specified as a value within a predefined range of values that may be mapped to one of a plurality of different sets of decompression constraints, where each set includes one or more compression constraints and corresponding parameters. Accordingly, in one or more examples, a tuning mechanism is provided that allows balancing decompression speed and the compression ratio in the form of, or using, a decompression level.

In block 304, compression framework 108 receives data 126, e.g., the data to be compressed. In block 306, compression framework 108 is capable of compressing data 126 using a compression technique, e.g., any of a variety of known compression techniques, employed by compression framework 108 (e.g., dictionary coder 120 and/or entropy coder 122) to generate compressed data as compressed data stream 128. Compression framework 108 compresses data 126 by enforcing the particular compression constraints 124 specified in block 302. The particular compression constraints that are enforced while compressing data may be observed by dictionary coder 120, entropy coder 122, or both dictionary coder 120 and entropy coder 122.

In block 308, compression framework 108 is capable of generating a metadata frame 130. Metadata frame 130 is a data structure that specifies the one or more particular compression constraints that were enforced while generating compressed data stream 128. Metadata frame 130 also specifies the particular parameters used for the compression constraints that were enforced. An example of a metadata frame is described in connection with FIGS. 5, 6, and 7. Further, compression framework 108 is capable of including metadata frame 130 within compressed data stream 128.

In one or more examples, compressed data stream 128 is format compliant. In other words, a client system that is executing a conventional decompressor is capable of decompressing compressed data stream 128 despite not including any decompressors specifically optimized to handle enforced compression constraints and despite not having the capability to detect the particular compression constraints enforced through detecting and/or decoding a metadata frame.

In block 310, compression framework 108 is capable of outputting compressed data stream 128 and metadata frame 130. In one or more examples, metadata frame 130 is included within compressed data stream 128. For example, metadata frame 130 may be included with compressed data stream 128, e.g., as part of a compressed data stream.

In an example use case, compressed data stream 128, with metadata frame 130, may be stored in a database or other data storage device and/or system. Compressed data stream 128, inclusive of metadata frame 130, may be stored as part of a content delivery system for delivery to one or more client systems such as client system 150 upon request. Compressed data stream 128, inclusive of metadata frame 130, for example, may be delivered to a plurality, e.g., many, requesting client devices.

As an illustrative and non-limiting example, host system 102 or another data processing system that is part of a content delivery system (e.g., a streaming platform) may deliver compressed data stream 128, inclusive of metadata frame 130 to many (e.g., hundreds, thousands, or more) client systems upon receiving a request from each such client system for the data (e.g., a digital asset or an item of digital content such as a song, movie, audio, video, image, audiovisual material, etc.).

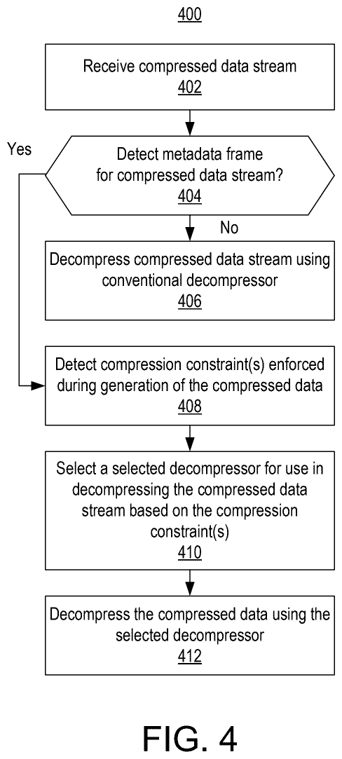

FIG. 4 illustrates a method 400 of decompressing data in accordance with one or more examples of the disclosed technology. Method 400 may be performed by client system 150 and, more particularly, by client system 150 through execution and/or implementation of decompression framework 160. Method 400 may be used to decompress data that has been compressed in accordance with the implementations described within this disclosure and/or for data that has been compressed using available conventional compression techniques.

Referring to FIGS. 1 and 4, in block 402, decompression framework 160 is capable of receiving compressed data stream 128. In block 404, decompression framework 160 is capable of detecting whether compressed data stream 128 has or includes a metadata frame 130. For example, metadata frame 130 may be inserted within compressed data stream 128 at a predetermined location. In one or more examples, metadata frame 130 may be prepended at the beginning of compressed data stream 128. In response to detecting metadata frame 130, method 400 continues to block 408. In response to detecting no metadata frame 130 for compressed data stream 128, method 400 continues to block 406.

In one or more examples, decompression framework 160 is capable of detecting the presence or inclusion of metadata frame 130 in that metadata frame 130 may begin with a predetermined bit pattern, also referred to as a “magic word,” that is detectable by decompression framework 160. Decompression framework 160 is capable of checking bits of compressed data stream 128 for the magic word and, in response to detecting bits of compressed data stream 128 that match the magic word, determining that a metadata frame for the compressed data has been detected.

Continuing with block 406 in the case where no metadata frame 130 is detected, decompression framework 160 is capable of providing compressed data stream 128 to a conventional decompressor. The conventional decompressor is one that is not optimized for handling compressed data with any particular compression constraints having been in effect while compressing the data. The lack of metadata frame 130 for compressed data stream 128 indicates that compressed data stream 128 was compressed using a conventional compression technique without enforcement of any compression constraints. Accordingly, the compressed data stream is provided to a conventional decompressor and decompressed using a conventional decompression technique.

Continuing with block 408, in the case where metadata frame 130 has been detected for compressed data stream 128, decompression framework 160 is capable of detecting compression constraints in force during generation of compressed data stream 128. For example, decompression framework 160 is capable of decoding the particular compression constraints and corresponding parameters from metadata frame 130.

In block 410, decompression framework 160 is capable of selecting a decompressor from a plurality of available decompressors to decompress compressed data stream 128. For example, decompression framework 160 may include a plurality of decompressors, where each decompressor is optimized to decompress compressed data streams generated with particular compression constraints in effect. Decompression framework 160 is capable of matching the compression constraints and parameters read from metadata frame 130 with the capabilities of the plurality of decompressors to select a particular decompressor that is best suited, or matched, to decompressing compressed data stream 128. In other words, the selected decompressor is one that will decompress compressed data stream 128 in the least amount of time.

In block 412, compressed data stream 128 is decompressed by the selected decompressor. That is, compressed data stream 128 is provided to the selected decompressor. The selected decompressor decompresses compressed data stream 128. Accordingly, in executing decompression framework 160, client system 150 is capable of recovering data 126, as the data existed prior to compression by compression framework 108. As noted, the compression-decompression is lossless in nature. Once decompressed, data 126 may be used by client system 150. For example, data 126 may be rendered if audio, visual, or audio-visual content by client system 150. It should be appreciated that the particular data that is compressed may be any of a variety of digital data and the particular examples provided herein are not intended to be limiting.

In one or more examples, though not illustrated in the figures, compressed data that includes a metadata frame also may be decompressed by a conventional decompressor. In one or more examples, a conventional decompressor may overlook or ignore the metadata frame and continue with decompressing the compressed data. The inclusion of the metadata frame does not hinder operation of conventional decompression operations. That is, the conventional decompressor is still capable of decompressing compressed data stream 128 despite the inclusion of a metadata frame therein. For example, metadata frame 130 may be placed within a skippable frame that is supported by the particular compression format used for decompression thereby allowing a conventional decompressor to read the metadata frame 130 and skip or ignore the metadata frame 130.

Even in cases where a conventional decompressor is used to decompress a compressed data stream generated with one or more compression constraints in effect during compression, the conventional decompressor is typically able to decompress the compressed data stream faster, or in less runtime, than had the compressed data stream been generated without any compression constraints having been in effect. In other words, despite the conventional decompressor not knowing the particular compression constraints that were enforced during compression, the fact that any compression constraints were enforced still allows a conventional decompressor to operate, e.g., to decompress the compressed data stream, faster or in less runtime than had the compressed data stream been generated without any compression constraints having been in effect.

FIG. 5 illustrates a data structure 500 for a metadata frame in accordance with one or more implementations of the disclosed technology. In the example of FIG. 5, data structure 500 includes two 8-byte segments shown as segments 502 and 504. The first 8-byte segment, e.g., segment 502, specifies the magic word that is detectable by decompression framework 160. For purposes of illustration, the magic word may be specified as ““AOCL_FDS.” It should be appreciated that any of a variety of other bit patterns may be used so long as compression framework 108 and decompression framework 160 utilize the same agreed upon magic word. The second 8-byte segment, e.g., segment 504, includes metadata specifying different compression constraints to be enabled and parameters for each compression constraint that is to be enabled for compressing data.

FIG. 6 is a table 600 illustrating the different compression constraints that may be specified in the second 8-byte segment 504 of a metadata frame. In the example, metadata frame 130 may specify up to nine different compression constraints numbered 1-9. As illustrated, a metadata frame may include additional space for future expansion and/or development. In FIG. 6, N is a non-zero value specified by the available number of bits for each respective constraint. The value specified for N for each compression constraint may be different. That is, use of the variable N is not intended to mean that the same value must be specified for each of the constraints listed. Rather, N may be specified independently and, as such, have a same or different value for one or more or each different compression constraint.

Compression constraint 1 may be specified by bits 0-5 of segment 504. Compression constraint 1 indicates whether short offsets, e.g., in reference to the match distance parameter illustrated in connection with FIGS. 2A and 2B, are permitted during compression. In other words, compression constraint 1 may be used to indicate a minimum offset for a match candidate within a search buffer. A value of 0 indicates that compression constraint 1 is not enforced. That is, a value of 0 indicates that data was compressed without any minimum imposed on the length of offset (or match distance). If a value N is specified, no offsets less than 2\hat{ }N bytes are permitted or used by dictionary coder 120 while compressing data. In this regard, compression constraint 1 may specify a minimum offset. Offsets less than 2\hat{ }N bytes in the search buffer, for example, are rejected.

The offset specifies how far away from the current position in the data being compressed a match may be found. Referring to FIGS. 2A and 2B, the offset illustrated is 8. Setting the minimum offset to 8, per compression constraint 1 would require specifying N=3 in the metadata frame. In a modern hardware processor that uses Single Instruction Multiple Data (SIMD) instructions, multiple bytes of data may be processed at one time to support vectorized operations. This type of hardware processor architecture means that multiple bytes of data are processed simultaneously. Short offsets limit SIMD copies.

For example, in the case where the hardware processor is capable of operating on a vector of 256 bytes of data at one time, and a match is found within the 256 bytes, the hardware processor is unable to accommodate this situation as the source data overlaps with the destination data. That is, the matched pattern cannot be within the vector being processed by an SIMD hardware processor. Such pattern must reside outside of the bytes currently processed. A scalar compute unit (e.g., a scalar hardware processor) would be needed to handle the foregoing example. The scalar compute unit, however, is slower than the vector hardware processor (e.g., the SIMD hardware processor) in that the scalar compute unit processes fewer bytes simultaneously thereby requiring more clock cycles. By imposing compression constraint 1, use of vector hardware processors is assured. In one or more examples, when imposing compression constraint 1, the minimum size of the offset may be set such that 2\hat{ }N is greater than or equal to the number of bytes that may be processed at one time by the vector hardware processor.

Compression constraint 2 may be specified by bits 6-11 of segment 504. Compression constraint 2 indicates whether long offsets, e.g., in reference to the match distance parameter illustrated in connection with FIGS. 2A and 2B, are permitted during compression. In other words, compression constraint 2 may be used to indicate a maximum offset for a match candidate within a search buffer. A value of 0 indicates that compression constraint 2 is not enforced. That is, a value of 0 indicates that data was compressed without any maximum length of offset (or match distance) being imposed. If a value N is specified, no offset greater than or equal to 2\hat{ }N bytes is permitted or used by dictionary coder 120 while compressing the data. In this regard, compression constraint 2 may specify a maximum offset such that offsets greater than or equal to 2\hat{ }N bytes for the search buffer are rejected.

Long offsets may increase cache misses in the hardware processor. Accordingly, in one or more examples, the maximum offset may be set to be less than or equal to the cache size of the hardware processor being used. By enforcing compression constraint 2 as discussed, matched bytes to be copied for a given match-distance pair are assured to be within the cache of the hardware processor.

Compression constraint 3 may be specified by bits 12-17 of segment 504. Compression constraint 3 indicates whether short matches, e.g., in reference to the match length parameter described in connection with FIGS. 2A and 2B, are permitted during compression. A value of 0 indicates that compression constraint 3 is not enforced. That is, a value of 0 indicates that data was compressed without any minimum length for matched bytes being imposed. If a value N is specified, no matches less than N bytes are permitted or used by dictionary coder 120 while compressing data. Compression constraint 3 recognizes that handling smaller amounts of data is often less efficient than handling larger amounts of data in a computer system. Short match lengths are correlated with slower decompression. For example, within computing architectures, it is often more efficient to copy a plurality of bytes in amounts such as 8 or 16 bytes of data at one time rather than implementing a plurality of smaller copy operations of 3, 4, or 5 bytes. Copying literals is more efficient than implementing multiple short copy operations. In this regard, compression constraint 3 may specify a minimum match length.

Compression constraint 4 may be specified by bits 18-23 of segment 504. Compression constraint 4 indicates whether long matches, e.g., in reference to the match length parameter as discussed in connection with FIGS. 2A and 2B, are permitted during compression. A value of 0 indicates that compression constraint 4 is not enforced. That is, a value of 0 indicates that data was compressed without imposing any maximum length for matched bytes during compression. If a value N is specified, no matches great than or equal to 2\hat{ }N bytes are permitted or used by dictionary coder 120. Compression constraint 4 places a cap or limit on the match length, which allows or facilitates loop unrolling in copy routines corresponding to faster decompression. In this regard, compression constraint 4 may specify a maximum match length. Example values that may be specified for N in for compression constraint 4 may include values in ranges of 8 to 10. Compression constraint 4 provides a runtime improvement by reducing the number of instructions and branching in program code as a loop may be converted into a fixed set of instructions. If maximum length is unknown a priori, one needs a loop to address the unknown maximum length and this loop may not be unrolled.

Compression constraint 5 may be specified by bits 24-29 of segment 504. Compression constraint 5 indicates whether short literals, e.g., in reference to the literal length parameter discussed in connection with FIGS. 2A and 2B, are permitted during compression. A value of 0 indicates that compression constraint 5 is not enforced. That is, a value of 0 indicates that data was compressed without any restriction as to the minimum number of literals. If a value N is specified, then no literals of less than N are permitted or used by dictionary coder 120 while compressing data. Compression constraint 5, like compression constraint 3, recognizes that handling smaller amounts of data is often less efficient than handling larger amounts of data in a computer system. Enforcing compression constraint 5 forces the parsing of at least a minimum number of literals in the data prior to accepting a match. For purposes of illustration, values such as 8 or 16 bytes may be specified.

Compression constraint 6 may be specified by bits 30-31 of segment 504. In particular compression techniques, special codes may be used to represent repeated offsets of matched data. For example, compression techniques such as ZSTD and LZMA support repeated offset codes or “rep codes.” These special codes require additional processing resources and/or cycles to track prior matches during decompression. Compression constraint 6 may be activated to impose a limit on how many repeated offset candidates can be used. Limiting repeated offset candidates means that a smaller buffer of past offsets may be maintained during decompression. The lower the number, the fewer repeated codes that need to be tracked by dictionary coder 120, which can result in faster decompression speed. In the example, the number of repeated offsets may be set, or restricted, to 00 (all rep codes supported); 01 (1 less than the maximum rep code is supported); 10 (2 less than the maximum number of rep codes is supported); and 11 (no rep codes are supported).

Compression constraint 7 may be specified by bit 32 of segment 504. In particular compression techniques, one or more external dictionaries may be used for matching purposes beyond simply attempting to match prior byte strings seen in the input data stream. Compression constraint 7 allows one to control whether an external dictionary may be used for compressing data. A value of 1 (true) indicates that an external dictionary was or may have been used by dictionary coder 120 while compressing data. The data in the dictionary, for example, would not have been seen already in the data being compressed. A value of 0 (false) indicates that no external dictionary was used by dictionary coder 120 while compressing data. Explicitly indicating whether an external dictionary was used helps avoid having to check whether candidate offsets are outside of the search buffer during decompression. Imposing compression constraint 7 results in decompression framework 160 being able to decompress data faster (e.g., with less computational burden) as no checking (e.g., branching or other paths) for checking an external dictionary need be performed or executed.

Compression constraint 8 may be specified by bits 33-38 of segment 504. Compression constraint 8 indicates whether large bit codes are permitted during compression. A value of 0 indicates that compression constraint 8 is not enforced. That is, a value of 0 indicates that no limit as to the size of bit codes (e.g., total bits) was imposed by entropy coder 122 during data compression. If a value N is specified, the total bits of any bit code must be less than 2\hat{ }N. For example, in a scenario where N=3, the total bits of any bit code must be less than 8 during compression. In this case, entropy coder 122 is capable of breaking larger bit codes into smaller constituent bit codes. A 15-bit code, for example, may be broken out into a 7-bit code and an 8-bit code to meet the compression constraint. Compression constraint 8 limits the number of bits needed to decode a given sequence. Compression constraint 8 eliminates checks for large total bits that place extra computational load on the decompressing system to decompress the sequence.

Compression constraint 9 may be specified by bits 39-44 of segment 504. Compression constraint 9 indicates the periodicity at which entropy tables are to be learned. The periodicity may be specified in terms of a number of blocks. A value of 0 indicates that entropy tables are to be learned for each block. That is, entropy coder 122 generates entropy tables for each block. If a value N is specified, entropy tables are learned every N blocks. Thus, entropy coder 122 need only generate entropy tables every N blocks. Constraint 9 recognizes that for many different types of data, the entropy models will not change significantly over some number of blocks and do not need to be re-learned on a per block basis. Thus, the same entropy table may be re-used for N blocks. Learning periodically, e.g., every N blocks, speeds up compression and decompression. Re-using entropy tables across multiple blocks avoids the overhead of decoding and preparing the tables for every block during decompression. Imposing compression constraint 9 may result in a reduction in the amount of compression achieved, but also results in decompression framework 160 being able to decompress data faster (e.g., with less computational burden).

In the example of FIG. 6, reserved bits are optionally included. Inclusion of reserved bits allows for further expansion of metadata as provided in metadata frame 130.

For purposes of illustration, consider an example metadata frame such as that illustrated in Table 1.

TABLE 1

| Segment 502: Magic Word (8 bytes) | Segment 504: Metadata (8 bytes) |
|---|---|
| 0x5344 465F 4C43 4F41 | 0x0000 000D 8000 0004 |

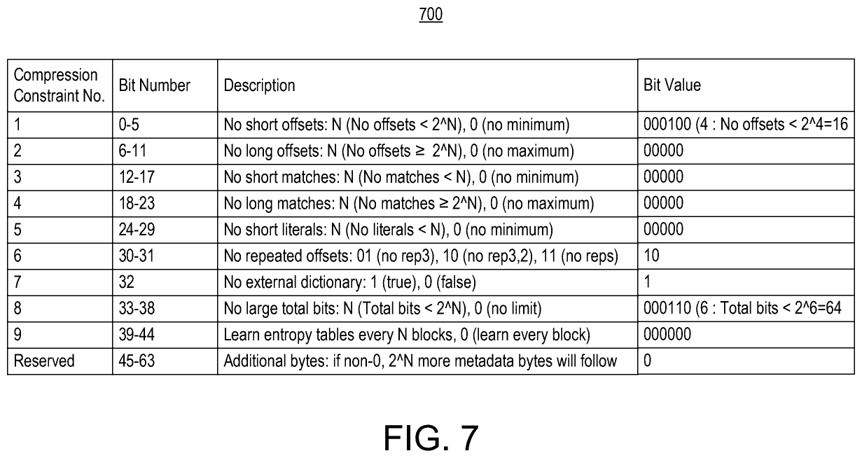

FIG. 7 is a table 700 illustrating the bit values specified for the metadata portion corresponding to segment 504.

As discussed, imposing compression constraints during compression improves decompression performance. Decompression performance may be further improved by providing a mechanism to inform decompression framework 160 that compression constraints were imposed. This mechanism may specify which compression constraints were imposed and optionally what the parameters for the compression constraint were as imposed. By informing decompression framework 160 of this information, certain branches and slower code paths that check for certain conditions and/or patterns in the compressed data may be eliminated thereby further increasing the decompression speed.

As discussed, in one or more examples, the metadata frame conveys this information. In one or more examples, for compression techniques that support skippable frames, e.g., ZSTD frame format and/or LZ4 frame format, the metadata frame may be packed into a skippable frame. This approach ensures that format compliance is achieved. In other examples, including for compression techniques that do not support skippable frames, the metadata frame may be included with compressed data stream 128 at a particular location such as at the beginning of compressed data stream 128. Legacy or conventional decompressors may skip the metadata frame and decompress the rest of the compressed data stream which remains format compliant.

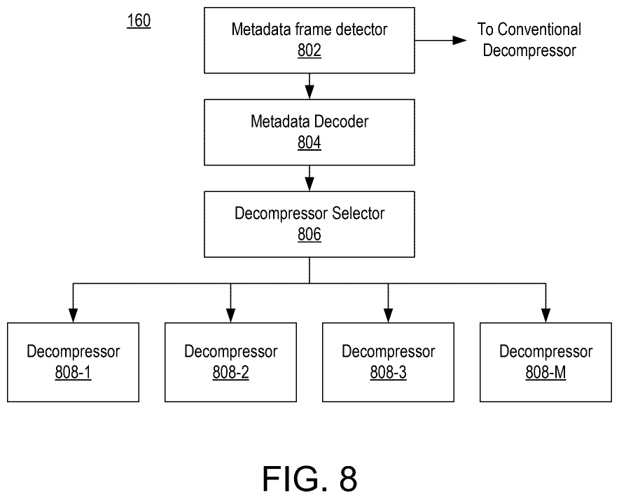

FIG. 8 illustrates decompression framework 160 in accordance with one or more implementations of the disclosed technology. In the example of FIG. 8, decompression framework 160 includes a metadata frame detector 802, a metadata decoder 804, a decompressor selector 806, and a plurality of different decompressors 808 (e.g., 808-1, 808-2, 808-3, through 808-M, where M is an integer value greater than 1).

In general, decompression framework 160, as illustrated in FIG. 8, is capable of providing optimized decompressor implementations. Each decompressor 808, for example, may be optimized to decompress data that was compressed using particular compression constraints and parameters. Each decompressor 808 may be curated to handle compressed data given a set of compression constraints in effect while generating the compressed data. This allows each decompressor 808 to operate on the data with greater computational efficiency (e.g., faster) in that unnecessary checks and/or program code paths or branches need not be included in the decompressor based on known conditions enforced during the compression process.

Metadata frame detector 802 is capable of parsing compressed data, e.g., a compressed data stream, and detecting whether a metadata frame is present or included in the compressed data. Metadata frame detector 802, for example, may search for the magic word (e.g., segment 502 of metadata frame 130) in the compressed data. In the event metadata frame detector 802 does not detect the magic word in the compressed data, metadata frame detector 802 may pass the compressed data to a conventional decompressor which may be included in decompression framework 160 (not shown) or executed as a separate entity than decompression framework 160.

In response to detecting the magic word, metadata decoder 804 is capable of decoding the bits from segment 504. As discussed, the bits specified in segment 504 specify which compression constraints were active or in effect when the received compressed data was generated (e.g., compressed by compression framework 108) and the particular parameters (e.g., N) for each compression constraint that was active.

Decompressor selector 806 is capable of receiving the bits as decoded from metadata decoder 804. Decompressor selector 806 may store a profile for each of decompressors 808. Each profile, for example, may specify a set of one or more compression constraints and corresponding parameters that the decompressor has been optimized to handle. Decompressor selector 806 is capable of selecting a decompressor 808 having a profile that matches, or most closely matches, the decoded bits from segment 504 of metadata frame 130 and provides the compressed data stream to the selected decompressor.

For example, decompressor 808-1 may be optimized to operate on a compressed data stream with compression constraint 1 having been imposed. Decompressor 808-2 may be optimized to operate on a compressed data stream with compression constraint 2 having been imposed. The particular number of decompressors 808 included is not intended to be limited and may be based on the particular set of compression constraints or combinations thereof that may be imposed or that are likely to be imposed at any given time. Further, additional decompressors 808 may be included that are optimized for different values of the parameters of the compression constraints.

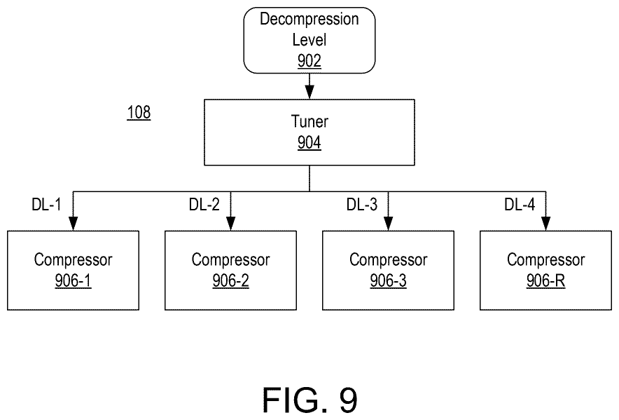

FIG. 9 illustrates another implementation of compression framework 108 in accordance with one or more implementations of the disclosed technology. In the example of FIG. 9, compression framework 108 includes a tuner 904 and a plurality of different compressors 906 (e.g., 906-1, 906-2, 906-3, through 906-R, where R is an integer value greater than 1). In one or more examples, each compressor 906 may include a dictionary coder 120 and an entropy coder 122, each being optimized as described herein for a particular set of one or more compression constraints. For example, compressor 906-1 may be configured to compress data while imposing compression constraint 1. Compressor 906-2 may be configured to compress data while imposing compression constraint 2. The particular number of compressors 906 included is not intended to be limited and may be based on the particular set of compression constraints or combinations thereof that may be imposed or that are likely to be imposed at any given time. Further, additional compressors 906 may be included that are optimized for different values of the parameters of the compression constraints.

Tuner 904 is capable of receiving a decompression level 902. Decompression level 902 may be a user-specified value that ranges from 1 to X, where X is an integer of one or more. Inclusion of tuner 904 allows a user to specify a particular decompression level 902 that balances decompression speed with the compression ratio achieved. The decompression level 902 may be specified a value within a range of values in which the low end of the range imposes the least number of compression constraints (e.g., no compression constraints) while the high end of the range imposes the most compression constraints. Fewer compression constraints provide better compression ratios (e.g., more compression) but result in less decompression speed. More compression constraints provide a poorer compression ratio (e.g., less compression) but a faster decompression speed. Each value in the range of values of decompression level 902 may be mapped to a different and particular set of compression constraints that are enforced while performing compression for the specified value.

In the example of FIG. 9, there are four different decompression levels available illustrated as DL-1, DL-2, DL-3, and DL-4 (e.g., 1, 2, 3, 4). In the example, tuner 904 is capable of selecting a particular compressor 906 to be used to compress received data 126 based on user-specified decompression level 902. Tuner 904 then provides data 126 to the selected compressor 906, which is configured to enforce the particular set of compression constraints mapped to the decompression level of the compressor. That is, compressor 906-1 is configured to enforce the particular compression constraints corresponding to decompression level DL-1 while compressing data. Compressor 906-2 is configured to enforce the particular compression constraints corresponding to decompression level DL-2 while compressing data. Compressor 906-3 is configured to enforce the particular compression constraints corresponding to decompression level DL-3 while compressing data, and so forth.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the implementations described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the implementations described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the implementations described herein.

Certain aspects of the implementations are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the disclosed technology. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various implementations of the disclosed technology have been presented for purposes of illustration but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A method, comprising:
generating, by computer hardware, a compressed data stream by compressing data using a data compression technique;
wherein the compressed data stream is generated while enforcing one or more compression constraints for the compression technique;
generating, by the computer hardware, a metadata frame specifying the one or more compression constraints; and
outputting, by the computer hardware, the compressed data stream including the metadata frame.

2. The method of claim 1, wherein the enforcing the one or more compression constraints includes using at least one of a minimum offset for a match candidate within a search buffer or a maximum offset for the match candidate within the search buffer.

3. The method of claim 1, wherein the enforcing the one or more compression constraints includes using at least one of a minimum match length or a maximum match length.

4. The method of claim 1, wherein the enforcing the one or more compression constraints includes parsing at least a minimum number of literals in the data prior to accepting a match.

5. The method of claim 1, wherein the enforcing the one or more compression constraints includes restricting a number of repeated offsets.

6. The method of claim 1, wherein the enforcing the one or more compression constraints includes restricting use of an external dictionary for specifying match candidates.

7. The method of claim 1, wherein the enforcing the one or more compression constraints includes limiting a number of bits generated by an encoder.

8. The method of claim 1, wherein the enforcing the one or more compression constraints includes using a same entropy table for an encoder for a predetermined number of blocks.

9. The method of claim 1, further comprising:
detecting the metadata frame for the compressed data stream;
detecting the one or more compression constraints enforced while generating the compressed data stream from the metadata frame; and
providing the compressed data stream to a selected decompressor of a plurality of decompressors, wherein the selected decompressor is selected based on the one or more compression constraints detected.

10. The method of claim 1, wherein the one or more compression constraints are specified as a decompression level; and
wherein the generating the compressed data stream includes selecting a selected compressor from a plurality of compressors based on the decompression level and compressing the data using the selected compressor.

11. A method, comprising:
in response to receiving a compressed data stream, checking, by computer hardware, the compressed data stream for a metadata frame;
in response to detecting the metadata frame, detecting, by the computer hardware and from the metadata frame, one or more compression constraints enforced during generation of the compressed data stream;
selecting a selected decompressor from a plurality of different decompressors based on the one or more compression constraints; and
decompressing, by the computer hardware, the compressed data stream using the selected decompressor.

12. The method of claim 11, wherein each decompressor of the plurality of different decompressors is optimized for decompressing compressed data streams for a particular set of the one or more compression constraints.

13. A system, comprising:
a hardware device capable of implementing operations including:
generating a compressed data stream by compressing data using a data compression technique;
wherein the compressed data stream is generated while enforcing one or more compression constraints for the compression technique;
generating a metadata frame specifying the one or more compression constraints; and
outputting the compressed data stream including the metadata frame.

14. The system of claim 13, wherein the enforcing the one or more compression constraints includes using at least one of a minimum offset for a match candidate within a search buffer or a maximum offset for the match candidate within the search buffer.

15. The system of claim 13, wherein the enforcing the one or more compression constraints includes using at least one of a minimum match length or a maximum match length.

16. The system of claim 13, wherein the enforcing the one or more compression constraints includes parsing at least a minimum number of literals in the data prior to accepting a match.

17. The system of claim 13, wherein the enforcing the one or more compression constraints includes restricting a number of repeated offsets.

18. The system of claim 13, wherein the enforcing the one or more compression constraints includes restricting use of an external dictionary for specifying match candidates.

19. The system of claim 13, wherein the enforcing the one or more compression constraints includes limiting a number of bits generated by an encoder.

20. The system of claim 13, wherein the enforcing the one or more compression constraints includes using a same entropy table for an encoder for a predetermined number of blocks.
